(19) United States
(12) Patent Application Publication
(10) Pub. No.: US 2021/0343543 A1
(43) Pub. Date: Nov. 4, 2021

(54) MANUFACTURING METHOD OF THIN FILM TRANSISTOR

(71) Applicant: WUHAN CHINA STAR OPTELECTRONICS SEMICONDUCTOR DISPLAY TECHNOLOGY CO., LTD., Wuhan, Hubei (CN)

(72) Inventor: Mingjen Lu, Wuhan, Hubei (CN)

(21) Appl. No.: 16/615,198

(22) PCT Filed: Jan. 8, 2019
(86) PCT No.: PCT/CN2019/070897

§ 371 Date: Nov. 20, 2019

(30) Foreign Application Priority Data
Dec. 3, 2018 (CN) 201811466103.1

(51) Int. Cl. H01L 21/322; H01L 21/02

(52) U.S. Cl. CPC H01L 21/3223; H01L 21/02694

(57) ABSTRACT

A manufacturing method of a thin film transistor is provided, which has advantages that there are sufficient hydrogen ions in an interlayer dielectric layer. In an annealing treatment, an amount of the hydrogen ions diffused into an active layer is sufficient, and the hydrogen ions enter a channel of the thin film transistor to fill non-bonded or unsaturated bonds of polysilicon atoms, thereby filling defects in the channel, repairing the defects of the active layer, reducing the number of unsteady states, and improving mobility and threshold voltage uniformity.

### FIELD OF DISCLOSURE

The present disclosure relates to the field of manufacturing liquid crystal display devices, and more particularly to a manufacturing method of thin film transistors.

### BACKGROUND

Liquid crystal displays (LCDs) have many advantages such as thin body, power saving, and no radiation, and have been widely used, for example, LCD televisions, mobile phones, personal digital assistants (PDAs), digital cameras, computer screens, or laptop screens, etc., such that the LCDs dominate the field of flat panel displays.

Organic light emitting diode (OLED) displays, also known as an organic electroluminescent displays, are emerging flat display devices. Because the OLED displays have advantages such as simple preparation process, low cost, low power consumption, high brightness, wide operating temperature range, light weight, fast response times, easy to realize color and large screen display, easy to implement and match with integrated circuit driver, easy to implement flexible display, etc., the OLED displays have broad application prospects. The OLED display devices can be classified in two types, which are passive matrix OLED (PMOLED) and active matrix OLED (AMOLED), namely direct addressing and thin-film transistor (TFT) matrix addressing, according to how they are driven.

TFTs are a main driving component in current liquid crystal display devices and active matrix driven organic electroluminescent display devices, and are directly related to development direction of high performance flat display devices. The thin film transistor has various structures, and material of the thin film transistor for manufacturing a corresponding structure is also various. At present, an active layer of the thin film transistor mainly uses amorphous silicon (a-Si), but the thin film transistor using amorphous silicon as the active layer has a low mobility, and it is difficult to meet driving requirements of a peripheral circuit. Therefore, low temperature polysilicon (LTPS) is used instead of amorphous silicon. Due to atoms of the low temperature polysilicon are arranged regular, carrier mobility is high. For a voltage-driven liquid crystal display device, the low temperature polysilicon thin film transistor can realize a deflection driving of liquid crystal molecules using a smaller size thin film transistor because of its high mobility, which greatly reduces a volume occupied by the thin film transistor and increases a light transmission area, so as to achieve higher brightness and resolution. For current-driven active matrix driven organic electroluminescent display devices, low temperature polysilicon thin film transistors can better meet drive current requirements.

The low temperature polysilicon thin film transistor structure is mainly formed by using excimer laser as a heat source and which is projected on a glass substrate of an amorphous silicon structure, so that the amorphous silicon structure absorbs energy of the excimer laser and transforms into a polysilicon structure.

FIG. 1 is a schematic structural diagram of a low temperature polysilicon thin film transistor in the prior art. As shown in FIG. 1, the conventional low temperature polysilicon thin film transistor has following manufacturing processes. Firstly, a buffer layer 2 and an amorphous silicon layer are sequentially formed on a substrate 1. The amorphous silicon layer is subjected to laser irradiation to realize a crystalline transition to a polysilicon layer. The polysilicon layer is then etched to form a plurality of polysilicon islands, thereby forming an active layer of the thin film transistor. The active layer further forms a first channel 3, an N⁺ region 31, an N⁻ region 32, a second channel 4, and a P⁺ region 41 by doping, and on this basis, a gate insulating layer 5 and a gate 6 are formed. Thereafter, a dielectric layer (ILD) 7 is formed, and it subjects to high temperature activation and hydrogenation. Then, a source 8 and a drain 9 are formed, thereby completing a fabrication of the low temperature polysilicon thin film transistor.

In the above processes, doping may cause lattice damage of the polysilicon, and a subsequent activation process is required to activate implanted ions and repair the lattice damage of the polysilicon layer. In addition, an interface between the polysilicon film and the gate insulating layer has a dangling bond of a non-bonding orbital, which is an important factor for increasing an interface state density of a grain boundary of the polysilicon. As a result, performance degradation of the display device such as a decrease in carrier mobility and a rise in threshold voltage is caused, and a subsequent process also passes through a hydrogenation process to passivate internal and interface defects of the polysilicon film.

In a conventional process, the hydrogenation process is performed after the formation of the gate and dielectric layers. H+ in the dielectric layer 7 is diffused into the polysilicon by a high temperature process to compensate for the defects of the polysilicon. However, this process has the following disadvantages: First, currently, there is no good and effective hydrogenation mechanism, and the product is often unable to fix when it is electrically abnormal; Second, hydrogen ions content in the ILD process is very limited, it is unable to provide sufficient hydrogen ions source for hydrogenation, resulting in increased costs; Third. if the hydrogen ions content in the ILD process is increased, a quality of the product will be poor. Therefore, the performances of activation and hydrogenation in conventional processes are not satisfactory.

### SUMMARY OF DISCLOSURE

The technical problem to be solved by the present invention is to provide a manufacturing method of a thin film transistor, which can repair defects of an active layer, thereby preventing from decreasing performance of the thin film transistor due to a large number of defects and dangling bonds in the channel, reducing the number of unsteady states, and improving mobility and threshold voltage uniformity.

In order to solve the above problems, the present invention provides a manufacturing method of a thin film transistor, comprising: providing a substrate; forming an active layer which is patterned over the substrate, wherein the active layer is a polysilicon active layer; forming a gate dielectric layer on the active layer which is patterned; forming a gate layer which is patterned on the gate dielectric layer; forming an interlayer dielectric layer on the gate layer, wherein the interlayer dielectric layer comprises a first interlayer dielectric layer and a second interlayer dielectric layer; and implanting hydrogen ions into the interlayer dielectric layer and performing an annealing treatment, wherein the hydrogen ions are diffused to the active layer through the interlayer dielectric layer, and the active layer is subjected to a hydrogenation treatment.

In one embodiment, temperature of the annealing treatment ranges between 330 degrees Celsius and 400 degrees Celsius.

In one embodiment, after the hydrogenation treatment, the manufacturing method further comprises: forming a source hole and a drain hole inside the interlayer dielectric layer and the gate dielectric layer, wherein the source hole corresponds to a source region of the active layer, and the drain hole corresponds to a drain region of the active layer; and correspondingly forming a source and a drain in the source hole and the drain hole.

In order to solve the above problems, the present invention also provides a manufacturing method of a thin film transistor, comprising: providing a substrate; forming an active layer which is patterned over the substrate; forming a gate dielectric layer on the active layer which is patterned; forming a gate layer which is patterned on the gate dielectric layer; forming an interlayer dielectric layer on the gate layer; and implanting hydrogen ions into the interlayer dielectric layer and performing an annealing treatment, wherein the hydrogen ions are diffused to the active layer through the interlayer dielectric layer, and the active layer is subjected to a hydrogenation treatment.

In one embodiment, the active layer is a polysilicon active layer.

In one embodiment, the interlayer dielectric layer comprises a first interlayer dielectric layer and a second interlayer dielectric layer.

In one embodiment, temperature of the annealing treatment ranges between 330 degrees Celsius and 400 degrees Celsius.

In one embodiment, after the hydrogenation treatment, the manufacturing method further comprises: forming a source hole and a drain hole inside the interlayer dielectric layer and the gate dielectric layer, wherein the source hole corresponds to a source region of the active layer, and the drain hole corresponds to a drain region of the active layer; and correspondingly forming a source and a drain in the source hole and the drain hole.

The present disclosure has advantages that an external hydrogen ions source is additionally provided while the interlayer dielectric layer and the gate dielectric layer which contain hydrogen ions, so that there are sufficient hydrogen ions in the interlayer dielectric layer. In the annealing treatment, an amount of the hydrogen ions diffused into the active layer is sufficient, and the hydrogen ions enter a channel of the thin film transistor to fill non-bonded or unsaturated bonds of polysilicon atoms, thereby filling defects in the channel, repairing the defects of the active layer, preventing from decreasing performance of the thin film transistor due to a large number of defects and dangling bonds in the channel, reducing the number of unsteady states, and improving mobility and threshold voltage uniformity.

### BRIEF DESCRIPTION OF DRAWINGS

FIG. 1 is a schematic structural diagram of a low temperature polysilicon thin film transistor in the prior art.

FIG. 2 is a flowchart of manufacturing a thin film transistor.

FIG. 3A to FIG. 3H are schematic diagrams showing manufacturing a thin film transistor.

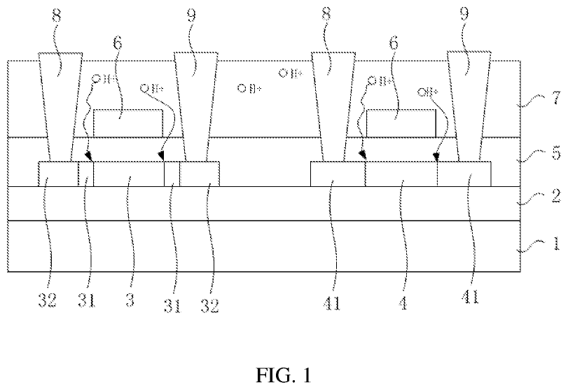

### DETAILED DESCRIPTION

Specific embodiments of a manufacturing method of a thin film transistor provided by the present disclosure will be described in detail below with reference to accompanying drawings.

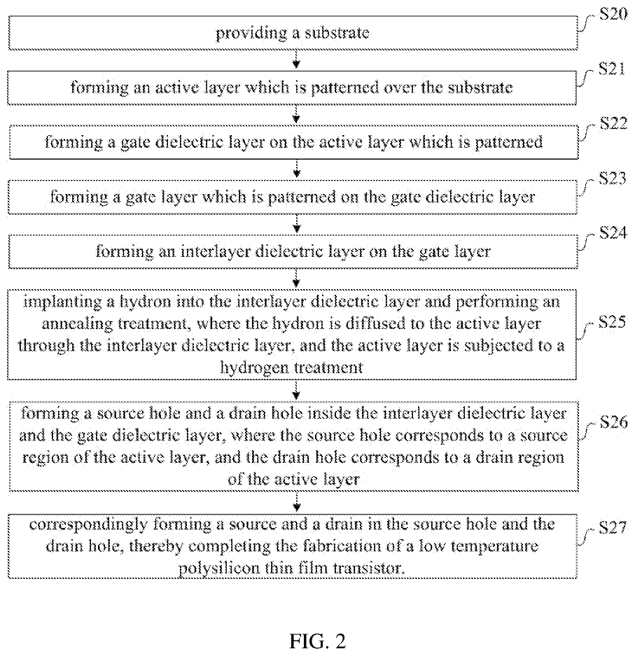

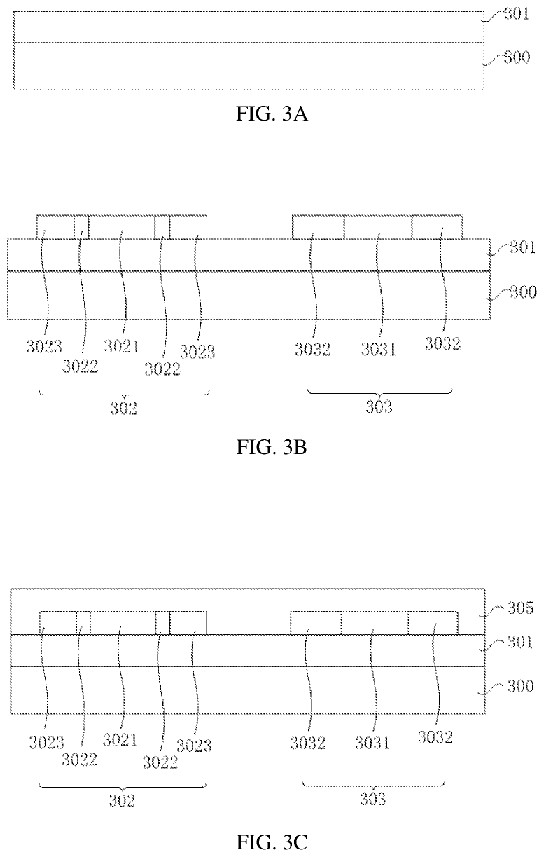

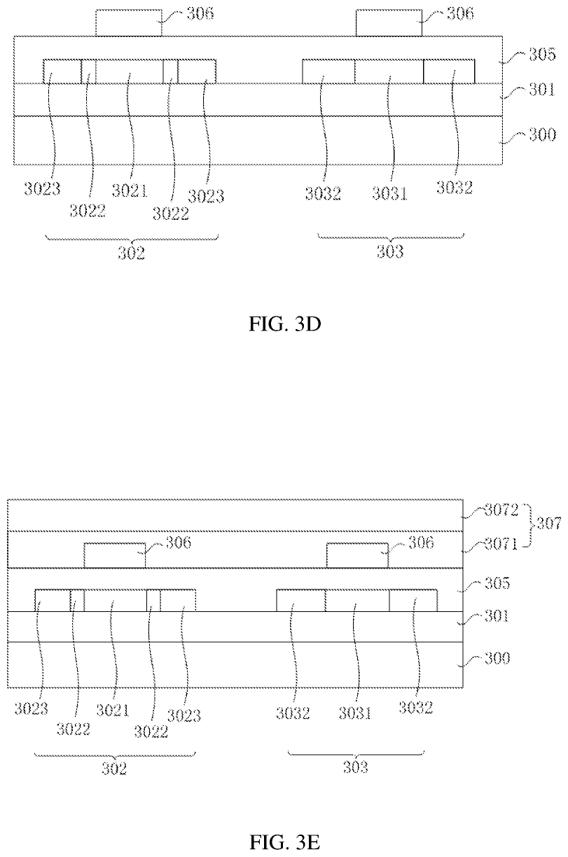

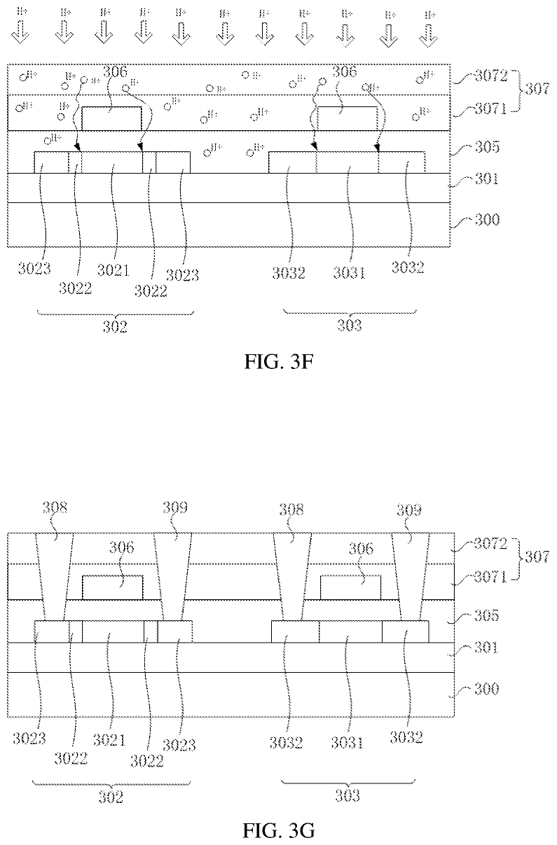

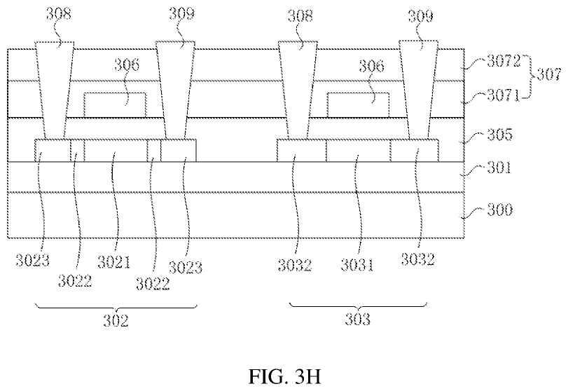

The present disclosure provides a manufacturing method of a thin film transistor. FIG. 2 is a flowchart of manufacturing a thin film transistor. FIG. 3A to FIG. 3H are schematic diagrams showing manufacturing a thin film transistor.

Referring to a step S20 and FIG. 3A, a substrate 300 is provided. The substrate 300 may include a hard substrate (such as a glass substrate and a ceramic substrate) and a flexible substrate (such as a plastic substrate or a substrate formed by a suitable material). After this step, a step of forming a buffer layer 301 on the substrate 300 is further included. The buffer layer 301 may be made of silicon nitride or silicon oxide, and may be formed by chemical vapor deposition (CVD).

Referring to a step S21 and FIG. 3B, a patterned active layer is formed on the substrate 300. In this embodiment, an active layer is formed on the buffer layer 301. The active layer may be a polysilicon. The formation method of the polysilicon active layer includes, but is not limited to, forming an amorphous silicon layer on the buffer layer 301. The amorphous silicon layer is subjected to laser irradiation to realize a crystalline transition to a polysilicon layer, and then the polysilicon layer is etched to form two polysilicon islands, i.e., a first active layer 302 and a second active layer 303. The method of the present disclosure is not only applicable to a case where the active layer is polysilicon, but also applies to a case where the active layer is other materials but needs to be hydrogenated.

Furthermore, the first active layer 302 is doped to form a first channel 3021, N⁺ regions 3022, and N⁻ regions 3023, where two N⁺ regions 3022 are oppositely disposed on both sides of the first channel region 3021, and two N⁻ regions 3023 are oppositely disposed on two outsides of the N⁺ regions 3022. The second active layer 303 is doped to form a second channel 3031 and P⁺ regions 3032, where two P⁺ regions 3032 are oppositely disposed on both sides of the second channel 3031. The method of doping includes, but is not limited to, ion implantation.

Referring to a step S22 and FIG. 3C, a gate dielectric layer 305 is formed on the patterned active layer. In this step, a gate dielectric layer 305 is deposited on the buffer layer 301, the first channel 3021, the N⁺ regions 3022, the N⁻ regions 3023, the second channel 3031, and the P⁺ regions 3032 by a chemical vapor deposition method. Also, the first channel 3021, the N⁺ regions 3022, the N⁻ regions 3023, second channel 3031, and the P⁺ regions 3032 are encapsulated in the gate dielectric layer 305. The gate dielectric layer 305 includes, but is not limited to, a silicon dioxide layer.

Referring to a step S23 and FIG. 3D, a patterned gate layer 306 is formed on the gate dielectric layer 305. The patterned gate layer 306 is formed by depositing a metal layer on the gate dielectric layer 305. The metal layer is patterned by etching or the like, thereby forming the patterned gate layer 306. The gate layer 306 can be made of a conventional metal material in the art, such as metallic molybdenum.

Referring to a step S24 and FIG. 3E, an interlayer dielectric layer 307 is formed on the gate layer 306. Material of the interlayer dielectric layer 307 includes, but is not limited to, SiOx or SiNx. In this embodiment, the interlayer dielectric layer 307 includes a first interlayer dielectric layer 3071 and a second interlayer dielectric layer 3072, which are sequentially formed on the gate layer 306. The first interlayer dielectric layer 3071 is SiOx, and the second interlayer dielectric layer 3072 is SiNx. The present disclosure is not limited thereto, and other configurations may be employed in other embodiments.

Referring to a step S25 and FIG. 3F, hydrogen ions are implanted to the interlayer dielectric layer 307, and an annealing treatment is performed. The hydrogen ions are diffused to the active layer through the interlayer dielectric layer 307, and the active layer is subjected to a hydrogenation treatment. In this step, sufficient hydrogen ions are supplied to the interface dielectric layer 307 to enable sufficient hydrogen ions to be transmitted to the active layer, thereby hydrogenating the active layer to repair defects of the active layer.

An ion implantation technique, such as a plasma ion implantation immersion technique or an ion bath doping technique, is employed to implant hydrogen ions. These methods are conventional methods of ion implantation and will not be described again.

When the hydrogen ions are implanted into the interlayer dielectric layer 307, the thin film transistor is heated to be subjected to the annealing treatment to diffuse the hydrogen ions to the active layer, thereby repairing defects of the active layer. Temperature of the annealing treatment ranges between 330 degrees Celsius and 400 degrees Celsius.

Referring to a step S26 and FIG. 3G, a source hole 308 and a drain hole 309 are respectively formed in an internal layer of the interlayer dielectric layer 307. The source hole 308 corresponds to a source region of the active layer, and the drain hole 309 corresponds to a drain region of the active layer. The method of forming the source hole 308 and the drain hole 309 may be a method known in the art, such as etching.

Referring to a step S27 and FIG. 3H, a source 310 and a drain 311 are respectively formed in the source hole 308 and the drain hole 309, thereby completing the fabrication of the low temperature polysilicon thin film transistor. The source 310 and the drain 311 can be formed by photolithography and etching processes.

In the present disclosure, an external hydrogen ions source is additionally provided while the interlayer dielectric layer 307 and the gate dielectric layer 305 which contain hydrogen ions, so that there are sufficient hydrogen ions in the interlayer dielectric layer 307. In the annealing treatment, an amount of the hydrogen ions diffused into the active layer is sufficient, and the hydrogen ions enter a channel of the thin film transistor to fill non-bonded or unsaturated bonds of polysilicon atoms, thereby filling defects in the channel, repairing the defects of the active layer, preventing from decreasing performance of the thin film transistor due to a large number of defects and dangling bonds in the channel, reducing the number of unsteady states, and improving mobility and threshold voltage uniformity.

The above descriptions are merely preferable embodiments of the present disclosure. Any modification or replacement made by those skilled in the art without departing from the principle of the present disclosure should fall within the protection scope of the present disclosure.

The subject matter of the present disclosure can be manufactured and used in the industry with industrial applicability.

What is claimed is:

1. A manufacturing method of a thin film transistor, comprising:
providing a substrate;
forming an active layer which is patterned over the substrate, wherein the active layer is a polysilicon active layer;
forming a gate dielectric layer on the active layer which is patterned;
forming a gate layer which is patterned on the gate dielectric layer;
forming an interlayer dielectric layer on the gate layer, wherein the interlayer dielectric layer comprises a first interlayer dielectric layer and a second interlayer dielectric layer; and
implanting hydrogen ions into the interlayer dielectric layer and performing an annealing treatment, wherein the hydrogen ions are diffused to the active layer through the interlayer dielectric layer, and the active layer is subjected to a hydrogenation treatment.

2. The manufacturing method of the thin film transistor as claimed in claim 1, wherein temperature of the annealing treatment ranges between 330 degrees Celsius and 400 degrees Celsius.

3. The manufacturing method of the thin film transistor as claimed in claim 1, wherein after the hydrogenation treatment, the manufacturing method further comprises:
forming a source hole and a drain hole inside the interlayer dielectric layer and the gate dielectric layer, wherein the source hole corresponds to a source region of the active layer, and the drain hole corresponds to a drain region of the active layer; and
correspondingly forming a source and a drain in the source hole and the drain hole.

4. A manufacturing method of a thin film transistor, comprising:
providing a substrate;
forming an active layer which is patterned over the substrate;
forming a gate dielectric layer on the active layer which is patterned;
forming a gate layer which is patterned on the gate dielectric layer;
forming an interlayer dielectric layer on the gate layer; and
implanting hydrogen ions into the interlayer dielectric layer and performing an annealing treatment, wherein the hydrogen ions are diffused to the active layer through the interlayer dielectric layer, and the active layer is subjected to a hydrogenation treatment.

5. The manufacturing method of the thin film transistor as claimed in claim 4, wherein the active layer is a polysilicon active layer.

6. The manufacturing method of the thin film transistor as claimed in claim 4, wherein the interlayer dielectric layer comprises a first interlayer dielectric layer and a second interlayer dielectric layer.

7. The manufacturing method of the thin film transistor as claimed in claim 4, wherein temperature of the annealing treatment ranges between 330 degrees Celsius and 400 degrees Celsius.

8. The manufacturing method of the thin film transistor as claimed in claim 4, wherein after the hydrogenation treatment, the manufacturing method further comprises:
forming a source hole and a drain hole inside the interlayer dielectric layer and the gate dielectric layer, wherein the source hole corresponds to a source region of the active layer, and the drain hole corresponds to a drain region of the active layer; and
correspondingly forming a source and a drain in the source hole and the drain hole.
